(19) United States
(12) Patent Application Publication
(10) Pub. No.: US 2017/0200611 A1
(43) Pub. Date: Jul. 13, 2017

(54) MANUFACTURING METHOD OF MEMORY DEVICE

(71) Applicant: SK hynix Inc., Gyeonggi-do (KR)

(72) Inventors: In Su PARK, Gyeonggi-do (KR); Ki Jun YUN, Gyeonggi-do (KR); Ki Hong LEE, Gyeonggi-do (KR)

(21) Appl. No.: 15/182,062

(22) Filed: Jun. 14, 2016

(30) Foreign Application Priority Data
Jan. 7, 2016 (KR) 10-2016-0002181

(51) Int. Cl. H01L 21/266; H01L 21/308; H01L 21/768

(52) U.S. Cl. CPC H01L 21/266; H01L 21/7688; H01L 21/308

(57) ABSTRACT

A manufacturing method for a memory device includes forming a stack structure over a substrate, forming a mask pattern over the stack structure, forming a first vertical hole by patterning the stack structure using the mask pattern, implanting a dopant into a sidewall of the first vertical hole to form a first region, wherein the first region is exposed by the mask pattern; and removing the first region to form a second vertical hole.

### CROSS-REFERENCE TO RELATED APPLICATION

The present application claims priority to Korean patent Application No. 10-2016-0002181, filed on Jan. 7, 2016, the entire disclosure of which is herein incorporated by reference in its entirety.

### BACKGROUND

1. Field

An aspect of the present disclosure relates to a manufacturing method for a memory device, and more particularly, to a manufacturing method for a three-dimensional memory device.

2. Description of the Related Art

Memory devices may include volatile memory devices and nonvolatile memory devices. The volatile memory devices are memory devices which lose stored data when a power supply is cut off. The nonvolatile memory devices are memory devices are memory devices which retain stored data even when a power supply is cut off. Due to these characteristics, the nonvolatile memory devices are widely used as portable storage devices.

A memory device may include a memory cell array in which data is stored, a peripheral circuit configured to perform program, read, and erase operations of the memory cell array, and a control logic configured to control the peripheral circuit.

A memory cell array may include a plurality of memory blocks. As the degree of integration of memory devices increases, memory blocks having a three-dimensional structure have recently been developed. Three-dimensional memory blocks include vertical strings each including memory cells stacked in a vertical direction from a substrate.

Vertical strings may be arranged between bit lines and a source line. The vertical strings may include vertical channel layers and memory layers, and word lines stacked along the memory layers may be connected to the vertical strings. Memory cells are positioned between the memory layers and the word lines.

As the capacities of memory devices become large, the height of vertical strings has increased. As the height of the vertical strings increases, the degree of difficulty of a manufacturing process for the memory device increases.

### SUMMARY

Embodiments provide a manufacturing method for a memory device, in which sidewalls of vertical holes can be formed perpendicular to a substrate.

According to an aspect of the present disclosure, there is provided a method for manufacturing a memory device, the method including: forming a stack structure over a substrate; forming a mask pattern over the stack structure; forming a first vertical hole by patterning the stack structure using the mask pattern; implanting a dopant into a sidewall of the first vertical hole to form a first region, wherein the first region is exposed by the mask pattern; and removing the first region to form a second vertical hole.

According to an aspect of the present disclosure, there is provided a method of manufacturing a memory device, the method including: patterning a stack structure to form a first hole, wherein the patterned stack structure includes a first region and a second region, wherein the first region is located at a lower sidewall of the first hole, wherein the second region is covered by the first region, wherein the first and the second regions have the same etch rate as each other; changing an etch rate of the first region; and removing the first region.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of Illustration. It will be understood that when an element is referred to as being “between” two elements, it can be the only element between the two elements, or one or more intervening elements may also be present. Like reference numerals refer to like elements throughout.

FIG. 1 is a diagram illustrating a memory system according to an embodiment of the present disclosure.

FIG. 2 is a detailed diagram illustrating a memory chip shown in FIG. 1.

FIG. 3 is a perspective view illustrating a memory block having a three-dimensional structure according to an embodiment of the present disclosure.

FIG. 4 is a perspective view illustrating a memory block having a three-dimensional structure according to another embodiment of the present disclosure.

FIGS. 5A to 5D are sectional views illustrating a manufacturing method for a memory device according to an embodiment of the present disclosure.

FIGS. 6A to 6D are sectional views illustrating a manufacturing method for a memory device according to another embodiment of the present disclosure.

FIG. 7 is a diagram illustrating a memory system according to an embodiment of the present disclosure.

FIG. 8 is a diagram illustrating a schematic configuration of a computing system including a memory system according to an embodiment of the present disclosure.

### DETAILED DESCRIPTION

Hereinafter, exemplary embodiments of the present disclosure will be described in detail with reference to the accompanying drawings. However, the present disclosure is not limited to the embodiments but may be implemented in different forms. These embodiments are provided only for illustrative purposes and for full understanding of the scope of the present disclosure by those skilled in the art.

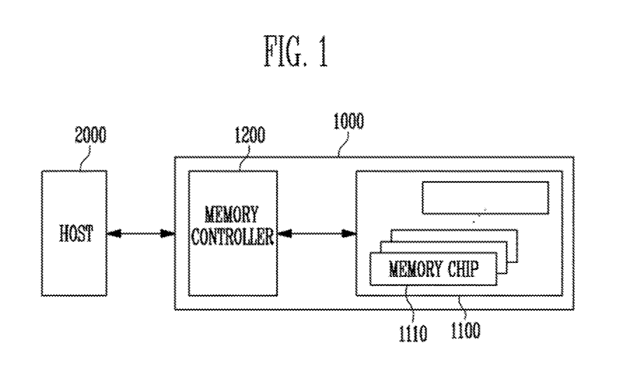

FIG. 1 is a diagram illustrating a memory system according to an embodiment of the present disclosure. Referring to FIG. 1, the memory system 1000 may include a memory device 1100 in which data is stored and a memory controller 1200 for controlling the memory device 1100.

The memory device 1100 may include a plurality of memory chips 1110. The memory chips 1110 may include a double data rate synchronous dynamic random access memory (DDR SDRAM), a low power double data rate 4 (LPDDR4) SDRAM, a graphics double data rate (GDDR) SRAM, a low power DDR (LPDDR), a Rambus dynamic random access memory (RDRAM), or a flash memory. In the following embodiment, the memory chip 1110 with a NAND flash memory will be described as an example.

The memory controller 1200 may control overall operations of the memory device 1100. The memory controller 1200 may output a command for controlling the memory device 1100, an address, and data, to the memory device 1100 or may receive data from the memory device 1100 in response to a command received from a host 2000.

The host 2000 may communicate with the memory system 1000 by using an interface protocol such as peripheral component interconnect-express (PCI-E), advanced technology attachment (ATA), serial ATA (SATA), parallel ATA (PATA), serial attached SCSI (SAS), and the like.

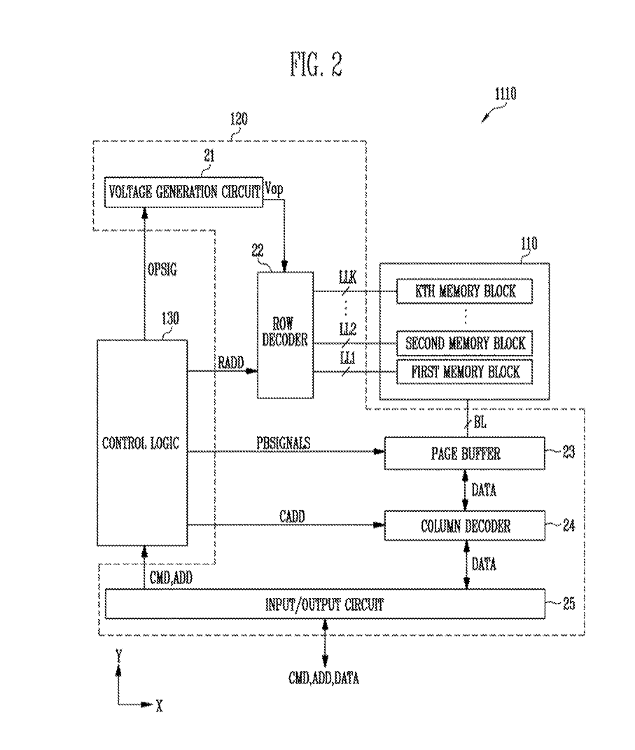

FIG. 2 is a detailed diagram illustrating the memory chip shown in FIG. 1. Referring to FIG. 2, the memory chip 1110 may include a memory cell array 110 in which data is stored, a peripheral circuit 120 configured to perform a program, read, or erase operation of the memory cell array 110, and a control circuit 130 configured to the peripheral circuit 120.

The memory cell array 110 may include first to Kth where K is a positive integer, memory blocks which are configured identically to each other. The first to Kth memory blocks may be connected to first to Kth local lines LL1 to LLK, respectively. The first to Kth memory blocks may be formed into a three-dimensional structure and may be configured identical to each other.

The peripheral circuit 120 may include a voltage generation circuit 21, a row decoder 22, a page buffer 23, a column decoder 24, and an input/output circuit 25. The voltage generation circuit 21 may generate operation voltages Vop having various levels in response to an operation signal OPSIG and may selectively apply the generated operation voltages Vop to global lines. If an operation signal OPSIG corresponding to a program, read, or erase operation is provided to the voltage generation circuit 21, the voltage generation circuit 21 may generate operation voltages Vop having various levels to perform the program, read, or erase operation.

The row decoder 22 transmits the operation voltage Vop to local lines connected to a selected memory block among the first to Kth local lines LL1 to LLK in response to a row address RADD. For example, the row decoder 22 may be connected to the voltage generation circuit 21 through the global lines. The row decoder 22 transmits the operation voltages Vop transmitted through the global lines to the local lines connected to the selected memory block.

The page buffer 23 is connected to the memory cell array 110 through bit lines BL. The page buffer 23 precharges the bit lines BL with a positive voltage, transmits/receives data to/from the selected memory block in program and read operations, or temporarily stores transmitted data in response to a page buffer control signal PBSIGNALS.

The column decoder 24 transmits/receives data DATA between the page buffer 23 and the input/output circuit 25 in response to a column address CADD. The input/output circuit 25 transmits a command CMD and an address ADD transmitted from the memory controller 1200 to the control logic 130, transmits data DATA transmitted from an external device to the column decoder 24, or outputs data DATA transmitted from the column decoder 24 to the external device.

The control logic 130 controls the peripheral circuit 120 In response to the command CMD and the address ADD. For example, the control logic 130 may output the operation signal OPSIG, the row address RADD, the page buffer control signal PBSIGNALS, and the column address CADD to control the peripheral circuit in response to the command CMD and the address ADD.

The above-described first to Kth memory blocks may be formed into a three-dimensional structure. Furthermore, the first to Kth memory blocks may be configured identical to each other.

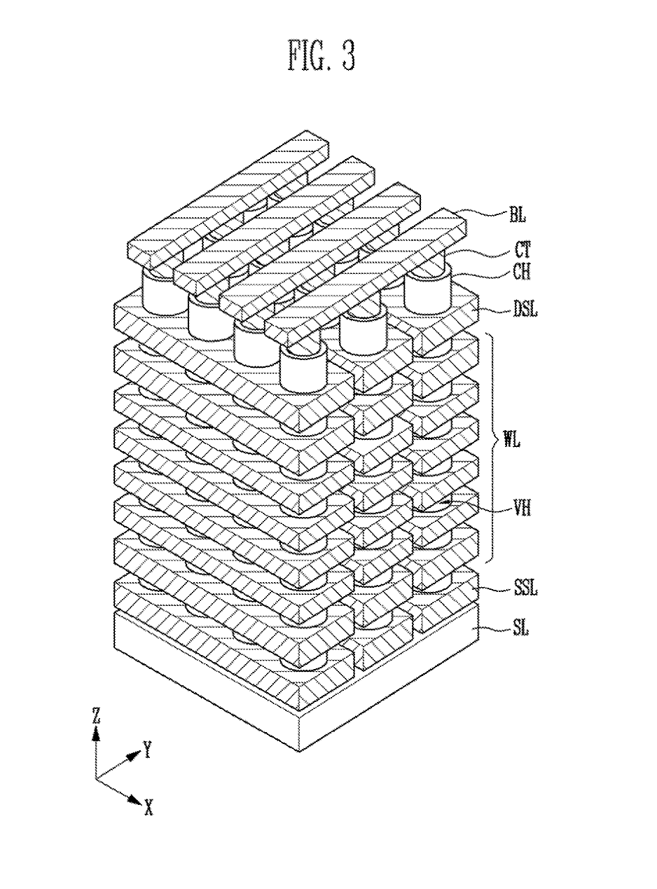

FIG. 3 is a perspective view illustrating a memory block having a three-dimensional structure according to an embodiment of the present disclosure. Referring to FIG. 3, the memory block having the three-dimensional structure may include I-shaped vertical strings. The I-shaped vertical strings are formed vertically that is, in a Z direction, over a substrate and arranged between bit lines BL and a source line SL. This structure may be referred to as a bit cost scalable (BiCS) structure. For example, when the source line SL is horizontally formed over the substrate, the vertical strings may be formed in the vertical direction for example, a Z direction, over the source line SL. More specifically, the vertical strings may include source select lines SSL, word lines WL, and drain select lines DSL, which are stacked over each other and spaced apart from each other. Although not shown in the drawings, the vertical strings may further include dummy select transistors or dummy memory cells.

Additionally, the vertical strings include vertical holes VH and vertical channel layers CH. The vertical holes VH vertically penetrate the source select lines SSL, the word lines WL, and the drain select lines DSL. The vertical channel layers CH are formed inside the respective vertical holes VH and contact the source line SL. Source select transistors are formed between the vertical channel layers CH and the source select lines SSL. Memory cells are formed between the vertical channel layers CH and the word lines WL. Drain select transistors are formed between the vertical channel layers CH and the drain select lines DSL.

Sizes of the source select transistors, the memory cells, and the drain select transistors may be determined according to a diameter of the vertical channel layers CH, and the diameter of the vertical channel layers CH may be determined according to a diameter of the vertical holes VH. Thus, when the diameter of the vertical holes VH is constant, sizes of the source select transistors, the memory cells, and the drain select transistors may also be constant.

The bit lines BL are in contact with tops of the vertical channel layers CH which are protruding upward from the drain select lines DSL, respectively. The bit lines BL extend along a Y direction and are spaced apart from each other along an X direction which is perpendicular to the Y direction. The source select lines SSL, the word lines WL, and the drain select lines DSL extend along the X direction and are spaced part from each other along the Y direction. Contact plugs CT may be further formed between the bit lines BL and the vertical channel layers CH.

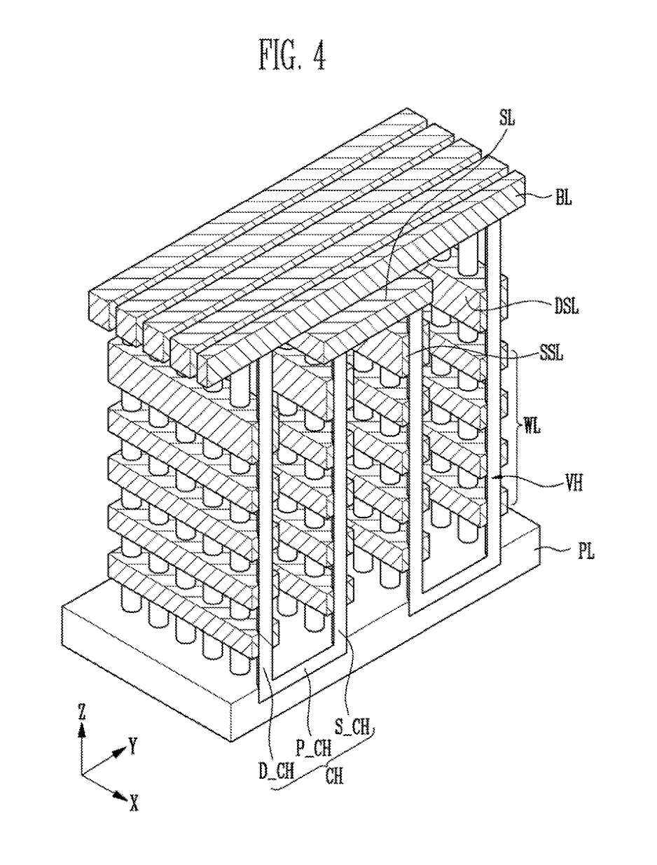

FIG. 4 is a perspective view illustrating a memory block having a three-dimensional structure according to another embodiment of the present disclosure.

Referring to FIG. 4, the memory block having the three-dimensional structure may include vertical strings which are formed vertically in a Z direction over a substrate. The vertical strings which are arranged between a pipe line PL and bit lines BL or a source line SL, and a pipe structure connect two strings to each other. More specifically, the vertical strings may include first sub-strings each of which is vertically arranged between the bit line BL and the pipe line PL, and second sub-strings each of which is vertically arranged between the source line SL and the pipe line PL. The first and second sub-strings are connected to each other through the pipe line PL, thus forming a U-shape in combination. This structure may be referred to as a pipe-shaped bit cost scalable (P-BiCS) structure.

For example, when the pipe line PL is horizontally formed over or in the substrate, the first and second sub-strings may be formed in the vertical direction over the pipe line PL. The first sub-strings may be formed between the bit lines BL and the pipe line PL, and the second sub-strings may be formed between the source line SL and the pipe line PL.

More specifically, the first sub-strings include word lines WL and drain select lines DSL, vertical holes VH vertically penetrating the word lines WL and the drain select lines DSL, and first vertical channel layers D_CH formed inside the respective vertical hoes VH. The drain select lines DSL are arranged in a Y direction and spaced apart from each other in the Y direction. Each of the drain select lines DSL extends in an X direction perpendicular to the Y direction. The drain select lines DSL are stacked in the Z direction and spaced apart from each other in the Z direction.

The second sub-strings include word lines WL, source select lines SSL, vertical holes VH vertically penetrating the word lines WL and the source select lines SSL, and second vertical channel layers S_CH formed inside the respective vertical holes VH. The source select lines SSL are arranged in the Y direction and spaced apart from each other in the Y direction. Each of the source select lines SSL extend in the X direction. The source select lines SSL are stacked in the Z direction and spaced apart from each other in the Z direction.

Memory cells are formed between the first vertical channel layers D_CH and the word lines WL and between the second vertical channel layers S_CH and the word lines WL. Source select transistors are formed between the second vertical channel layers S_CH and the source select lines SSL, and drain select transistors are formed between the first vertical channel layers D_CH and the drain select lines DSL.

Sizes of the source select transistors, the memory cells, and the drain select transistors may be determined according to diameters of the first and second vertical channel layers D_CH and S_CH. The diameters of the first and second vertical channel layers D_CH and S_CH may be determined according to a diameter of the vertical holes VH. Thus, when the diameter of the vertical holes VH is constant, sizes of the source select transistors, the memory cells, and the drain select transistors may also be constant.

The first vertical channel layers D_CH and the second vertical channel layers S_CH may be connected to each other through pipe channel layers P_CH in the pipe line PL. The bit lines BL are in contact with the tops of the first vertical channel layers D_CH which are protruding upward from the drain select lines DSL, and are spaced apart from each other along the X direction which is perpendicular to the Y direction. The source line SL is in contact with the tops of the second vertical channel layers S_CH which are protruding upward from the source select lines SSL. The source line SL extends in the X direction.

As described in FIGS. 3 and 4, when the diameter of the vertical holes VH is constant, sizes of the source select transistors, the memory cells, and the drain select transistors may also be constant. A manufacturing method for a memory device including vertical holes having a uniform diameter either at upper or at lower portions of the vertical hole will be described as follows.

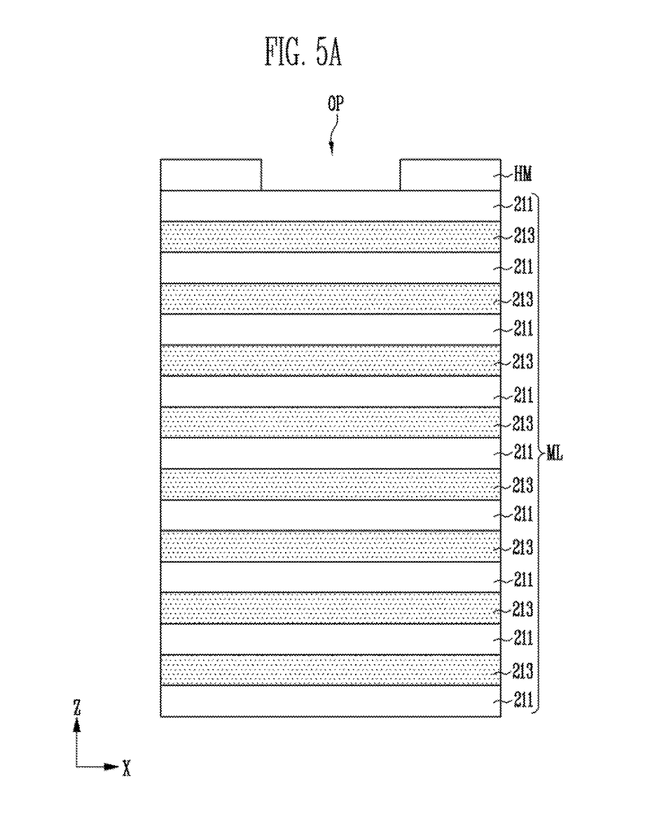

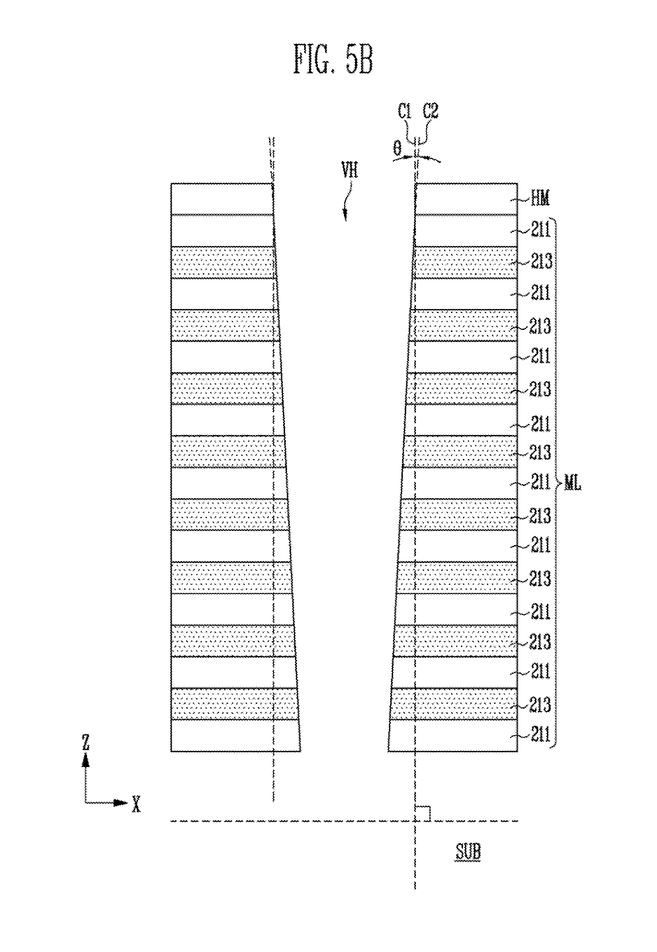

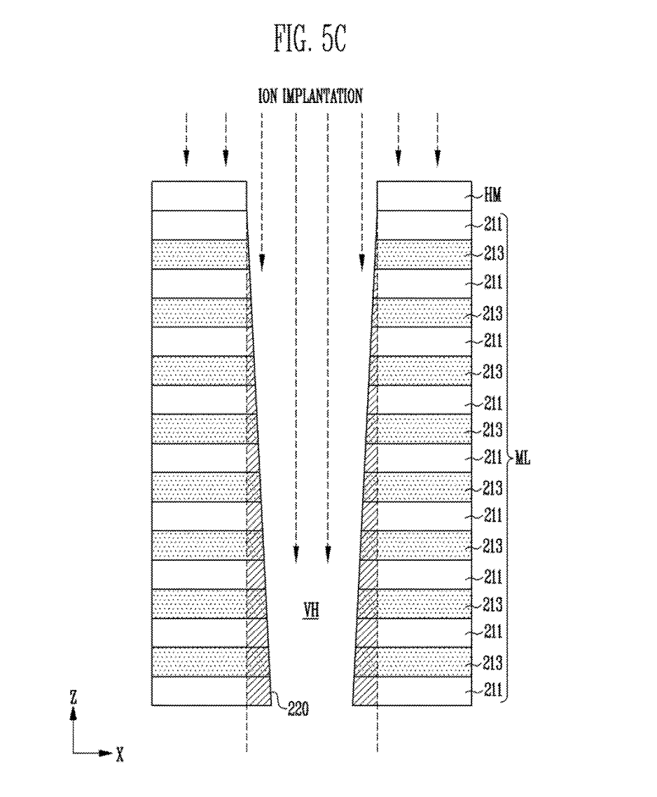

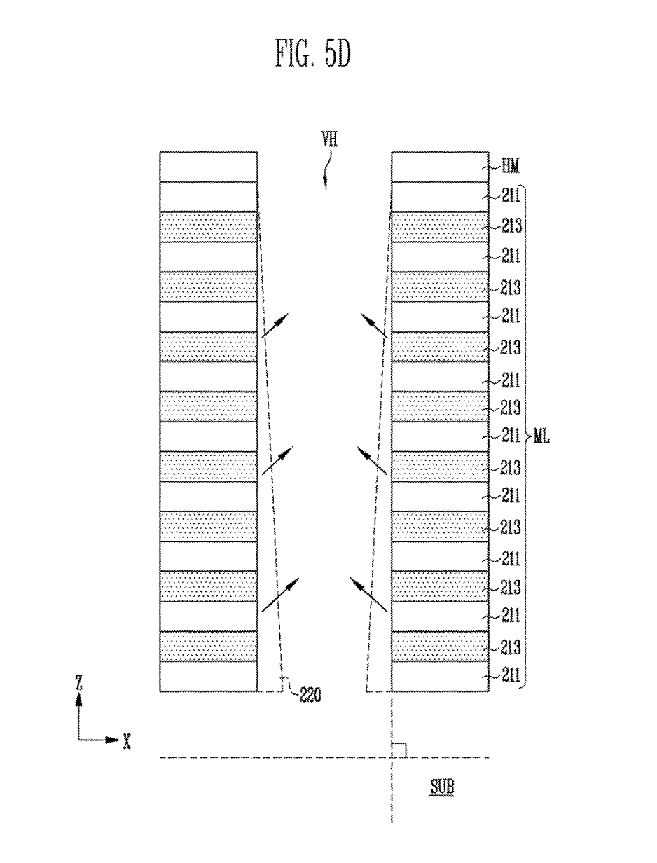

FIGS. 5A to 5D are cross-sectional views illustrating a manufacturing method for a memory device according to an embodiment of the present disclosure. Referring to FIG. 5A, first material layers 211 and second material layers 213 are alternately stacked on a substrate (not shown) including a lower structure, thereby forming a stack structure ML. The lower structure may include a source line or pipe line or may include a portion of a peripheral circuit.

The first material layers 211 may be formed of an insulating layer. For example, the first material layers 211 may be formed of an 2o oxide-based material such as a silicon oxide layer. The second material layers 213 may be formed of a sacrificial layer or conductive layer having an etching selection ratio with respect to the first material layers 211. For example, when the second material layers 213 are formed of a sacrificial layer, the second material layers 213 may be formed of a silicon nitride layer. When the second material layers 213 are formed of a conductive layer, the second material layers 213 may be formed of a tungsten layer.

Subsequently, a mask pattern HM is formed on the stack structure ML. The mask pattern HM may include an opening OP through which a portion of the stack structure ML is exposed. That is, a portion of the top surface of the stack structure ML is exposed through the opening OP formed in the mask pattern HM. The opening OP may be formed in a region in which a vertical hole will be formed.

Referring to FIG. 5B, a vertical hole VH penetrating the first and second material layers 211 and 213 is formed by performing an etching process using the mask pattern HM as a barrier. The etching process may be performed as an anisotropic dry etching process. It is preferred that the vertical hole VH is formed having a side surface or a sidewall (C1) perpendicular to an upper surface of the substrate SUB. However, it is difficult to form the side surface of the vertical hole VH perpendicular to the substrate SUB. Instead, the side surface of the vertical hole VH ends up with an inclination angle θ (C2).

Specifically, in the dry etching process, an upper portion of the stack structure ML is etched for a longer time as compared with a lower portion of the stack structure ML. Hence, the narrower the diameter of the vertical hole VH is, the deeper is the location of the vertical hole VH at which the diameter is measured.

Referring to FIG. 5C, an ion implantation process is performed using the mask pattern HM as a barrier. The ion implantation process is performed such that a dopant is implanted into the side surface of the vertical hole VH, that is, a side surface of the stack structure ML. For example, an inert element may be used as the dopant in the ion implantation process. The inert element may include Group XVIII elements of the Periodic Table. For example, argon (Ar) may be used as the dopant. Additionally argon (Ar) and boron (B), phosphorus (P), carbon (C), or a combination thereof may be used as the dopant.

The ion implantation process is performed as an anisotropic ion implantation process in which a dopant moves in the vertical direction. By the anisotropic ion implantation process, the dopant may be implanted into the side surface of the vertical hole VH which is exposed by the mask pattern HM. Thus, the dopant is not implanted into the stack structure ML covered by the mask pattern HM.

Upon implantation of a dopant, the region 220 into which the dopant is implemented has a different etching selection ratio from the stack structure ML which is not subject to the implantation. That is, a difference in etching selection ratio occurs between (i) the region 220, that is, a portion of the stack structure ML which is exposed by the mask pattern HM and subject to the implantation, and (ii) the stack structure ML which is not exposed by the mask pattern HM and thus is not subject to the implantation.

Referring to FIG. 5D, an etching process may be performed to remove the region 220 into which the dopant is implanted. The etching process may be performed as a wet etching process or a dry etching process. The dry etching process may be an isotropic dry etching process. The etching process may be performed using an echant having a different etching selection ratio between the region 220 into which the dopant is implanted and the stack structure ML into which the dopant is not implanted.

For example, a distilled water or hydrofluoric acid (HF) based etchant may be used as the etchant used in the wet etching process. The region 220 in which the dopant is implanted is removed due to the difference in etching selection ratio between the region 220 in which the dopant is implanted and the stack structure ML in which the dopant is not implanted. Accordingly, the inclination of the side surface of the vertical hole VH can be adjusted such that the side surface of the vertical hole VH is perpendicular to the substrate SUB.

As described above, when the side surface of the vertical hole VH is formed perpendicular to the substrate SUB, a vertical channel layer or the like is formed inside the vertical hole VH more easily and stably. In addition, even after the vertical channel layer or the like is formed inside the vertical hole VH, the diameter of the vertical channel layer can remain uniform either at its upper portion or at its lower portion. Thus, memory cells which are formed along the vertical channel layer can be formed in uniform thickness. Therefore, a variation in performance of the memory cells depending on location can be reduced, thereby improving reliability of a memory device.

Although the method for forming the vertical hole VH is described in the above-described embodiment, the above-described ion implantation and etching processes may be applied even when a trench is formed, so that a side surface of the trench can be vertically formed.

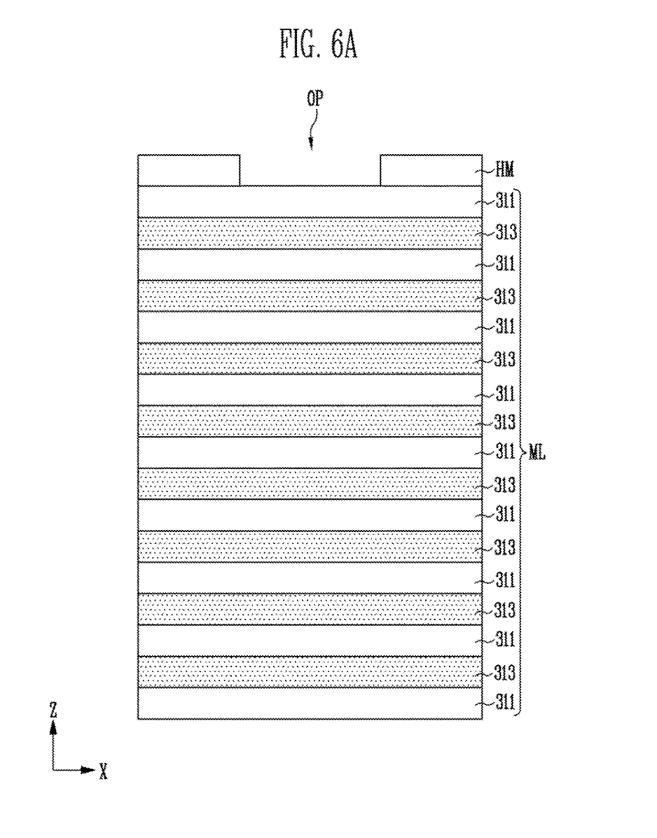

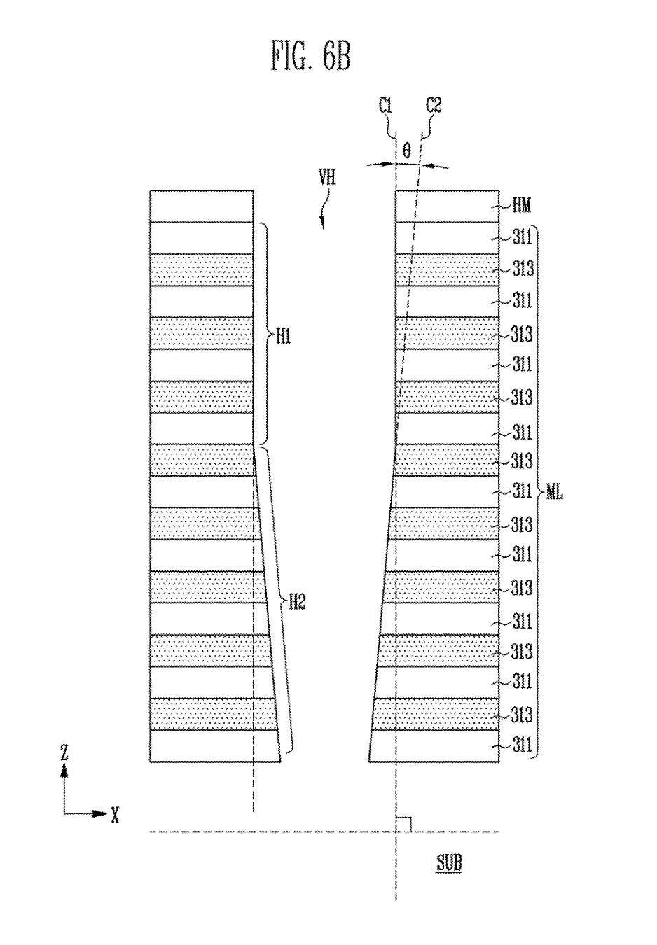

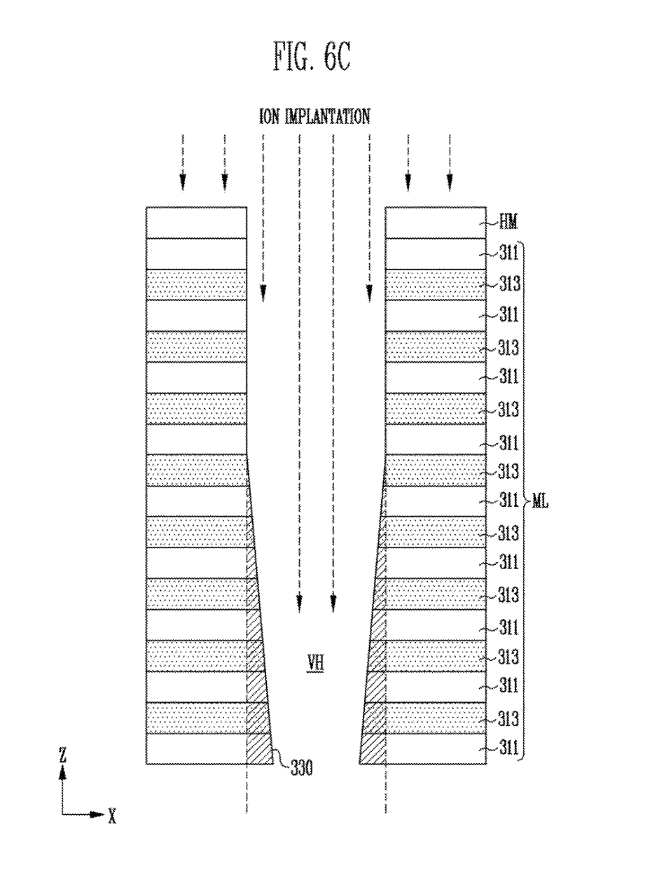

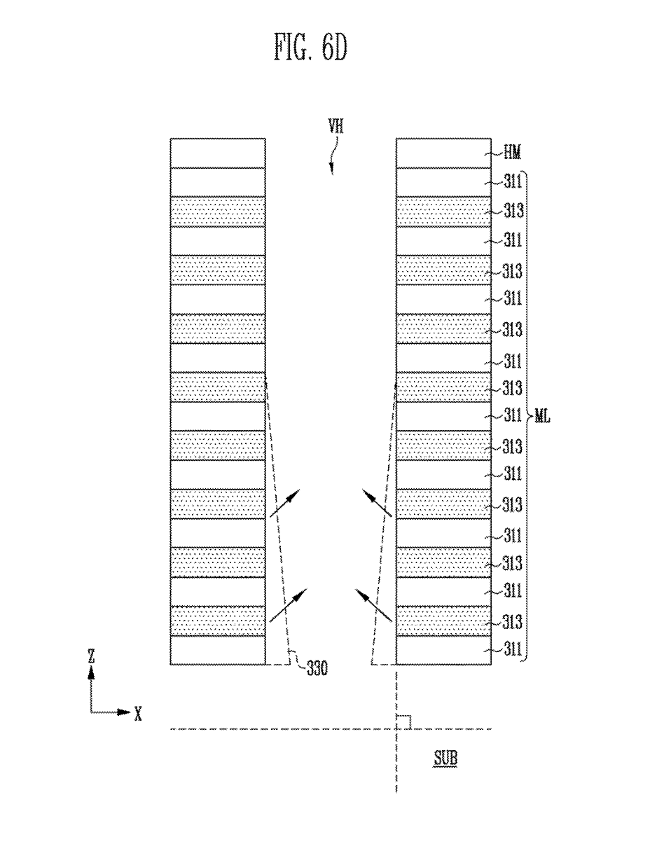

FIGS. 6A to 6D are sectional views illustrating a manufacturing method for a memory device according to another embodiment of the present disclosure. Referring to FIG. 6A, first material layers 311 and second material layers 313 are alternately stacked on a substrate (not shown) including a lower structure, thereby forming a stack structure ML. The lower structure may include a source line or pipe line or may include a portion of a peripheral circuit.

The first material layers 311 may be formed of an insulating layer. For example, the first material layers 311 may be formed of an oxide-based material such as a silicon oxide layer. The second material layers 313 may be formed of a sacrificial layer or a conductive layer and have an etching selection ratio with respect to the first material layers 311. For example, when the second material layers 313 are formed of a sacrificial layer, the second material layers 313 may be formed of a silicon nitride layer. When the second material layers 313 are formed of a conductive layer, the second material layers 313 may be formed of a tungsten layer.

Subsequently, a mask pattern HM is formed on the stack structure ML. The mask pattern HM may include an opening OP through which a portion of the stack structure ML is exposed. That is, a portion of the top surface of the stack structure ML is exposed through the opening OP formed in the mask pattern HM. The opening OP may be formed in a region in which a vertical hole will be formed.

Referring to FIG. 6B, a vertical hole VH penetrating the first and second material layers 211 and 213 is formed by performing an etching process using the mask pattern HM as a barrier. The etching process may be performed as an anisotropic dry etching process. It is desirable that the vertical hole VH has a side surface (C1) perpendicular to the substrate SUB which is formed by an anisotropic dry etching process. However, due to characteristics of the etching process, the vertical hole VH may be formed with an inclined side surface.

The side surface of the vertical hole VH has an inclination angle θ at a specific depth H1 (C2) which is measured from a top surface of the vertical hole VH. Specifically, in the dry etching process, an upper portion of the stack structure ML is etched for a longer time as compared with a lower portion of the stack structure ML. Hence, the vertical hole VH may have a side surface perpendicular to the substrate SUB at its upper portion, for example, from the top surface of the vertical hole VH to the specific depth H1. However, the diameter of the vertical hole VH may be reduced as it comes close to a depth H2 which is located at a lower level than the specific depth H1.

Referring to FIG. 6C, with the mask pattern HM on, an ion implantation process is performed to further etch a lower side surface of the vertical hole VH such that the entire side surface of the vertical hole VH is formed perpendicular to the substrate. The ion implantation process is performed such that a dopant is implanted into the lower side surface of the vertical hole VH, that is, a side surface H2 of the stack structure ML. The diameter at H2 gets narrower as it comes close to the bottom of the vertical hole VH.

For example, an inert element may be used as the dopant in the ion implantation process. The inert element may include Group XVIII elements of the Periodic Table. For example, argon (Ar) may be used as the dopant. Additionally, argon (Ar) and boron (B), phosphorus (P), carbon (C), or a combination thereof may be used as the dopant. The ion implantation process is performed by an anisotropic ion implantation process in which a dopant is guided to move in the vertical direction. In the anisotropic ion implantation process, the dopant is implanted straight from the upper portion to the lower portion of the vertical hole VH. Hence, the dopant may be implanted along the side surface of the vertical hole VH. Thus, the dopant is implanted into only a portion 330 of the stack structure ML. The portion 330 is exposed by the opening OP of the mask pattern HM. The dopant is not implanted into the stack structure ML formed under the mask pattern HM.

Upon implantation of a dopant, the region 330 into which the dopant is implemented has a different etching selection ratio from the stack structure ML into which the dopant is not implanted. That is, the Implantation causes a difference in etching selection ratio between the region 330 which is exposed to the inside of the vertical hole VH and the stack structure ML which is not exposed to the inside of the vertical hole VH.

Referring to FIG. 6D, upon completion of the implantation, the region 330 into which the dopant is implanted is removed by an etch process and a vertical sidewall is obtained. The etching process may be performed by a wet etching process or a dry etching process. The dry etching process may be performed by an isotropic dry etching process.

The etching process may be performed using an echant having a different etching selection ratio to the region 330 in which the dopant is implanted and to the stack structure ML in which the dopant is not implanted. For example, a distilled water or hydrofluoric acid (HF) based etchant may be used as the etchant in the wet etching process. By the etching process, the region 330 into which the dopant is implanted is removed due to the difference in etching selection ratio between the region 330 and the stack structure ML in which the dopant is not implanted. Accordingly, the inclined side surface of the vertical hole VH can be refined into a vertical side surface which is perpendicular to the substrate SUB.

As described above, the vertical side surface of the vertical hole VH enables a vertical channel layer or other structure to be formed inside the vertical hole VH with a uniform thickness. This is due to there being no difference in diameter or width of the vertical channel layer regardless of location. Thus, memory cells can be formed along the sidewall of the vertical channel layer with a uniform thickness or a uniform size. Thus, a variation in electrical performance depending on a location of the memory cells can be reduced, thereby improving reliability of the memory device.

Although the method of forming the vertical hole VH is described in the above-described embodiment, the above-described ion implantation and etching processes may be also applied when a trench is formed to form a trench with a vertical side surface.

FIG. 7 is a diagram illustrating a memory system according to an embodiment of the present disclosure. Referring to FIG. 7, the memory system 3000 may include a memory device 1100, in which data is stored, and a memory controller 1200 for controlling the memory device 1100. Moreover, the memory controller 1200 controls communication between a host 2000 and the memory device 1100. The memory controller 1200 may include a buffer memory 1210, a CPU 1220, an SRAM 1230, a host interface 1240, an ECC 1250, and a memory interface 1260.

The buffer memory 1210 temporarily stores data while the memory controller 1200 controls the memory device 1100. The CPU 1220 may perform a control operation for data exchange of the memory controller 1200. The SRAM 1230 may be used as a working memory of the CPU 1220. The host interface 1240 may be provided with a data exchange protocol of the host 2000 which is connected to the memory system 3000. The ECC 1250 is an error correction unit and may detect and correct errors which are included in data read out from the memory device 1100. The semiconductor interface 1260 may interface with the memory device 1100. Although not shown in FIG. 7, the memory system 3000 may further include a ROM (not shown) for storing code data for interfacing with the host 2000.

The host 2000 may include a computer, a ultra mobile PC (UMPC), a workstation, a net-book, a personal digital assistant (PDA), a portable computer, a web tablet, a wireless phone, a mobile phone, a smart phone, a digital camera, a digital audio recorder, a digital audio player, a digital video recorder, a digital video player, a device capable of transmitting/receiving information in a wireless environment, any electronic home network device, etc.

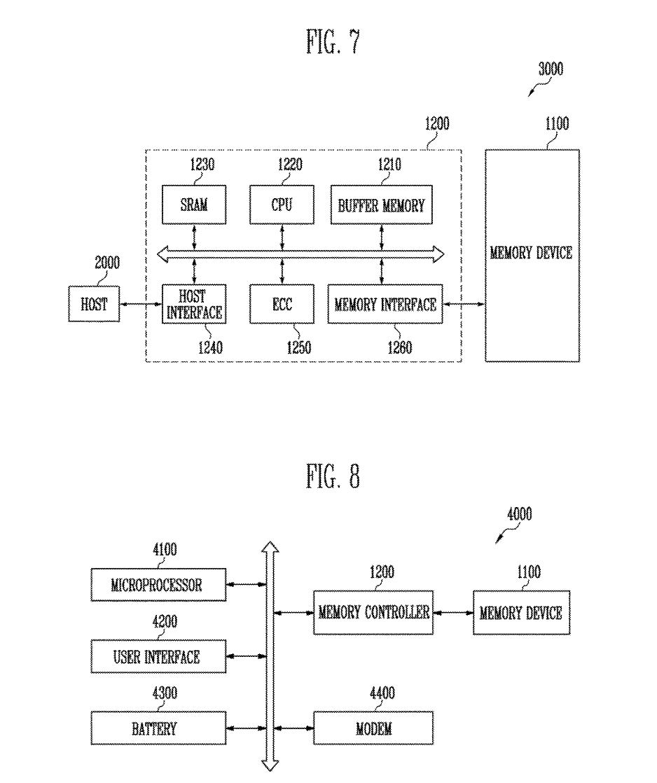

FIG. 8 is a diagram illustrating a computing system including a memory system according to an embodiment of the present disclosure. Referring to FIG. 8, the computing system 4000 may include a memory device 1110, a memory controller 1200, a microprocessor 4100, a user interface 4200, and a modem 4400, which are electrically connected to a bus. When the computing system 4000 is a mobile device, a battery 4300 for supplying operation voltages of the computing system 4000 may be additionally provided in the computing system 4000. Although not shown in the drawings, the computing system 4000 may further include an application chip set, a camera image processor (CIS), a mobile DRAM, and the like. The memory controller 1200 and the memory device 1110 may constitute a solid state drive/disk (SSD).

The computing system 4000 may be packaged in various forms. For example, the computing system 4000 may be packaged in a manner such as package on package (PoP), ball grid arrays (BGAs), chip scale packages (CSPs), plastic leaded chip carrier (PLCC), plastic dual in-line package (PDIP), die in Waffle pack, die in wafer form, chip on board (COB), ceramic dual in-line package (CERDIP), plastic metric quad flat pack (MQFP), thin quad flat pack (TQFP), small outline integrated circuit (SOIC), shrink small out line package (SSOP), thin small outline package (TSOP), thin quad flat pack (TQFP), system in package (SIP), multi-chip package (MCP), wafer-level fabricated package (WFP), or wafer-level processed stack package (WSP).

According to the present disclosure, a vertical hole with a vertical sidewall can be formed and be applied to a three-dimensional memory device. Thus, it is possible to form memory cells in a uniform size or thickness in the vertical hole. Accordingly, it is possible to reduce a variation in electrical characteristics or performance of the memory cells depending on locations of the memory cells, thereby improving reliability of the three-dimensional memory device.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A method for manufacturing a memory device, the method comprising:
forming a stack structure over a substrate;
forming a mask pattern over the stack structure;
forming a first vertical hole by patterning the stack structure using the mask pattern;
implanting a dopant into a sidewall of the first vertical hole to form a first region, wherein the first region is exposed by the mask pattern; and
removing the first region to form a second vertical hole.

2. The method of claim 1, wherein the stack structure includes first material layers and second material layers, which are alternately stacked over each other.

3. The method of claim 2, wherein each of the first material layers includes an insulating layer.

4. The method of claim 2, wherein each of the second material layers includes a sacrificial layer, and
wherein each of the second material layers has a different etching selection ratio from each of the first material layers.

5. The method of claim 4, wherein each of the second material layers includes a conductive layer, and
wherein each of the second material layers has a different etching selection ratio from each of the first material layers.

6. The method of claim 1, wherein the forming of the first vertical hole is performed by patterning the stack structure using an anisotropic dry etching process.

7. The method of claim 1, wherein the implanting of the dopant is performed using an ion implantation process.

8. The method of claim 6, wherein the ion implantation process is performed by an anisotropic ion implantation process.

9. The method of claim 1, wherein the dopant includes an inert element.

10. The method of claim 9, wherein the inert element includes one or more of Group XVIII elements.

11. The method of claim 1, wherein the removing of the first region is performed by a wet etching process, a dry etching process, or a combination thereof.

12. The method of claim 11, wherein the dry etching process is performed by an isotropic etching process.

13. The method of claim 11, wherein the removing of the first region is performed using different etching rates between a first portion in which the dopant is implanted and a second portion in which the dopant is not implanted of the stack structure.

14. A method for manufacturing a memory device, the method comprising:
patterning a stack structure to form a first hole, wherein the is patterned stack structure includes a first region and a second region, wherein the first region is located at a lower sidewall of the first hole, wherein the second region is covered by the first region, wherein the first and the second regions have the same etch rate as each other;
changing an etch rate of the first region; and
removing the first region.

15. The method of claim 14, wherein the changing of the etch rate of the first region is performed by an ion implanting process in the first region.

16. The method of claim 15, wherein the ion implantation process implants a dopant into the first region and makes the etch rate of the first region different from the second region.

17. The method of claim 16, wherein the dopant includes an inert element.

18. The method of claim 14, wherein the removing of the first region is performed using an etching process.

19. The method of claim 18, wherein the removing the first region is performed using different etch rates between the first region and the second region.

20. The method of claim 18, wherein the removing the first region is performed by a wet etching process, a dry etching process, or a combination thereof.
